(19) United States
(12) Patent Application Publication
(10) Pub. No.: US 2015/0179668 A1
(43) Pub. Date: Jun. 25, 2015

(54) THIN FILM TRANSISTOR ARRAY SUBSTRATE, METHOD FOR FABRICATING THE SAME AND DISPLAY

(71) Applicant: BOE Technology Group Co., Ltd., Beijing (CN)

(72) Inventor: Jing Niu, Beijing (CN)

(73) Assignee: BOE TECHNOLOGY GROUP CO., LTD., Beijing (CN)

(21) Appl. No.: 14/345,875

(22) PCT Filed: Jun. 26, 2013
(86) PCT No.: PCT/CN2013/077947

§ 371 Date: Mar. 19, 2014

(30) Foreign Application Priority Data
Apr. 1, 2013 (CN) 201310110533.0

(51) Int. Cl. H01L 27/12; H01L 33/58

(52) U.S. Cl. CPC H01L 27/124; H01L 27/1262; H01L 33/58

(57) ABSTRACT

A TFT array substrate, a method for fabricating the same and a display are disclosed. The TFT array substrate comprises: a plurality of gate lines, a plurality of data lines and a plurality of pixel regions defined by intersecting the plurality of gate lines and the plurality of data lines, a pixel electrode is disposed in each of the pixel regions. The TFT array substrate further comprises: a gate electrode formed on a substrate; a black matrix and an active layer sequentially formed above the gate electrode, the gate electrode and the active layer are isolated from each other via the black matrix overlaying the gate electrode; a source electrode and a drain electrode both formed on the active layer; a color filter layer formed on the source electrode, the drain electrode and the active layer; the pixel electrode is disposed on the color filter layer and connected to the drain electrode by way of a via hole penetrating through the color filter layer.

### FIELD OF THE ART

Embodiments of the invention relate to the filed of liquid crystal display (LCD) technologies, more particularly, to a thin film transistor (TFT) array substrate, a method for fabricating the same and a display.

### BACKGROUND

TFT LCDs dominate the current flat panel display market for the advantages of being compact, power saving and radiationless. For a TFT-LCD, the TFT array substrate and its fabrication method determine the performance, yield and price of the product.

A conventional TFT-LCD is formed by assembling a TFT array substrate and a color filter substrate to form a cell. Controlling switch TFTs and pixel electrodes are formed on the TFT array substrate, while red, green and blue filter layers and common electrodes are formed on the color filter substrate. Liquid crystal molecules are sandwiched between the two substrates to render colorful display under effect of an electrical field generated between the electrodes of the two substrates.

However, as for the novel color filter on array (COA) technology, it is not necessary to perform the assembling process, thus an increase in breadth of a light-shielding layer would not occur, which is beneficial for improving an aperture ratio.

FIG. 1 illustrates a cross section of a conventional COA TFT array substrate, in which a gate electrode 102 is formed on a substrate 1, disposed above the gate electrode 102 are a gate insulation layer 103 and an active layer 104, the gate electrode 102 and the active layer 104 being insulated by way of the gate insulation layer 103; a source electrode 105 and a drain electrode 106 are formed on the active layer 104; a protection layer 107 overlays the source electrode 105 and the drain electrode 106; a black matrix 108 and a color filter 109 are disposed on the protection layer 107, the black matrix 108 is also disposed directly above the source electrode 105 and the drain electrode 106, and the color filter 109 has three primary colors interleavingly arranged in a pixel region; a pixel electrode 110 is disposed as the upmost layer and connected to the drain electrode 106 by way of a via hole penetrating through the black matrix 108 and the protection layer 107.

Eight mask processes are required to finish fabricating such configured TFT array substrate to respectively form the gate electrode 102, the active layer 104 and the source/drain electrode (105, 106), the protection layer 107, the black matrix 108, the color filter 109 (three mask processes needed for three primary colors), and the pixel electrode 110, besides that, the arrangement of the gate insulation layer 103 and the protection layer 107 makes the whole process steps too many and complicated, lowering the defect-free rate.

### SUMMARY

An object of the invention is to provide a TFT array substrate, a method for fabricating the same and a display which can reduce the number of mask processes in the COA fabrication technology, simplify the process steps, significantly shorten the process time, reduce the process complexity and improve the production efficiency.

A first aspect of the invention provides a TFT array substrate, comprising a plurality of gate lines, a plurality of data lines and a plurality of pixel regions defined by intersecting the plurality of gate lines and the plurality of data lines, a pixel electrode is disposed in each of the pixel regions, the TFT array substrate further comprises:

a gate electrode formed on a substrate;

a black matrix and an active layer sequentially formed above the gate electrode, the gate electrode and the active layer are isolated from each other via the black matrix overlaying the gate electrode;

a source electrode and a drain electrode both formed on the active layer;

a color filter layer formed on the source electrode, the drain electrode and the active layer; the pixel electrode is disposed on the color filter layer and connected to the drain electrode by way of a via hole penetrating through the color filter layer.

As an example, a permittivity of a material of the black matrix is 4 to 5.

As an example, a material of the black matrix is photosensitive black resin with metal powder uniformly dispersed therein.

As an example, the metal powder is silver powder or copper powder or a mixture of them.

As an example, a width of the black matrix in an extension direction of the gate line is larger than a width of the gate line, and the width of the black matrix in an extension direction of the data line is larger than a width of the data line.

As an example, an orthographic projection of the black matrix on the substrate and that of the pixel electrode on the substrate partially overlap, in the extension direction of the gate line.

A second aspect of the invention further provides a display comprising any of the above TFT array substrate.

A third aspect of the invention further provides a method for fabricating a TFT array substrate comprising:

forming a gate electrode on a substrate;

forming a black matrix on the gate electrode;

sequentially forming an active layer, a source electrode and a drain electrode on the black matrix;

forming a color filter layer on the active layer, the source electrode and the drain electrode, the color filter layer has a via hole at a location corresponding to the drain electrode;

forming a pixel electrode on the color filter layer, the pixel electrode is connected to the drain electrode by way of the via hole in the color filter layer.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not imitative of the invention.

FIG. 1 schematically illustrates a configuration of a conventional TFT array substrate;

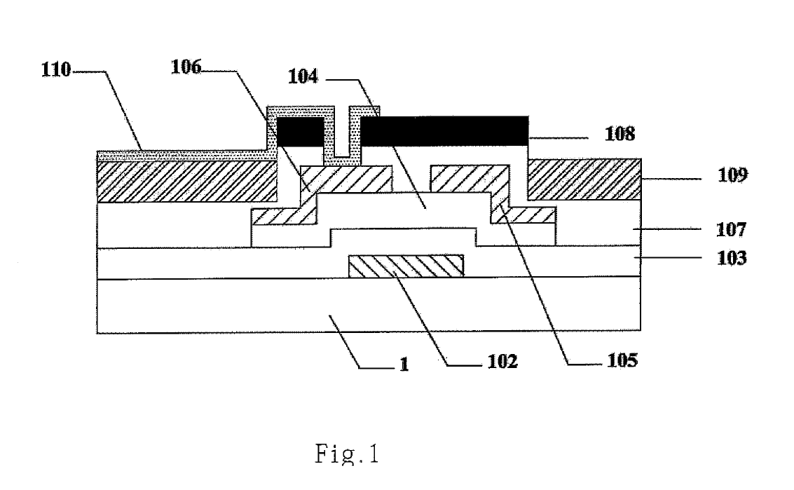

FIG. 2 schematically illustrates a configuration of a TFT array substrate in accordance with an embodiment of the invention;

FIG. 3 is a simplified top view of a TFT array substrate in accordance with an embodiment of the invention; and

FIG. 4 is a cross section view taken along A-A of FIG. 3.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

A TFT array substrate in accordance with an embodiment of the invention uses a photosensitive black resin as the gate insulation layer and as a black matrix which divides sub-pixels. Moreover, a small amount of metal powder (such as silver powder or copper powder and the like) may be further doped into the photosensitive black resin to lower its permittivity, thereby improving performance of the TFT.

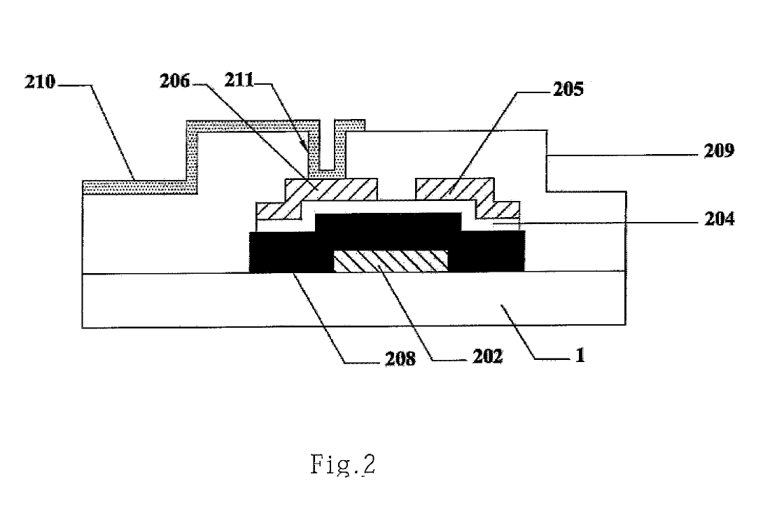

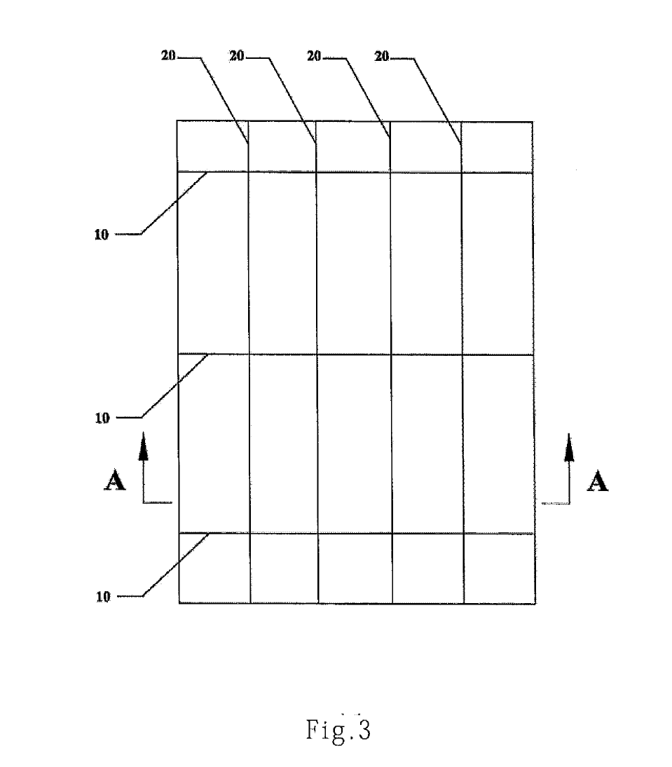

As illustrated in FIGS. 2 and 3, the TFT array substrate of the embodiment of the invention comprises a plurality of gate lines 10, a plurality of data lines 20 and a plurality of pixel regions defined by intersecting the plurality of gate lines 10 and the plurality of data lines 20, a pixel electrode 210 is disposed in each of the pixel regions, the TFT array substrate further comprises;

a gate electrode 202 formed on a substrate 1;

a black matrix 208, an active layer 204 sequentially formed above the gate electrode 202, the gate electrode 202 and the active layer 204 are isolated from each other via the black matrix 208 overlaying the gate electrode 202;

a source electrode 205 and a drain electrode 206 formed on the active layer 204;

a color filter layer 209 formed on the source electrode 205, the drain electrode 206 and the active layer 204; the pixel electrode 210 is disposed on the color filter layer 209 and connected to the drain electrode 206 by way of a via hole 211 in the color filter layer 209.

In the above TFT array substrate, the active layer 204 and the source/drain electrodes 205, 206 are directly disposed on the black matrix 208, the color filter layer respectively overlays each of the sub-pixel regions while covers the TFT region, which provide insulating protection for both data line 20 and the source/drain electrodes 205, 206 beneath the color filter layer. The TFT array substrate in accordance with the embodiment of the invention eliminates the disposition of the gate insulation layer and the protection layer, which reduces the number of the mask processes by one and significantly simplifies the method for fabricating the substrate. Meanwhile, two plasma vapor film formation processes are saved, which significantly shortens the process time and the process complexity, meanwhile effectively reducing the thickness of the substrate.

The color filter layer 209 may be a color filter layer of three primary colors comprising three regions of red, blue and green, which requires three mask processes to form. Therefore, a method for fabricating the TFT array substrate of the embodiment totally has seven mask processes, which significantly simplifies the method for fabricating the substrate, in comparison with the conventional eight-mask-process method. Meanwhile, two plasma vapor film formation processes are saved, which significantly shortens the process time, reduces the process complexity and the production cost.

Permittivity of a material of the black matrix 208 may be 4 to 5. The black matrix 208 overlays both the gate line 10 and the gate electrode 202, it can also shield the data line 20 thereabove.

As an example, a material of the black matrix 208 is for example a photosensitive black resin with metal powder uniformly dispersed therein. The addition of the metal powder will reduce the permittivity of the black matrix 208, so as to prevent the black matrix 208 functioning as the gate insulation layer from adversely affecting the TFT property. A proper amount of the added metal powder allows the permittivity of the black matrix 208 to be 4 to 5. The metal powder uniformly dispersed in the black matrix may be silver powder or copper powder or a mixture of both. As an example, a preferable material of the black matrix 208 is photosensitive black resin.

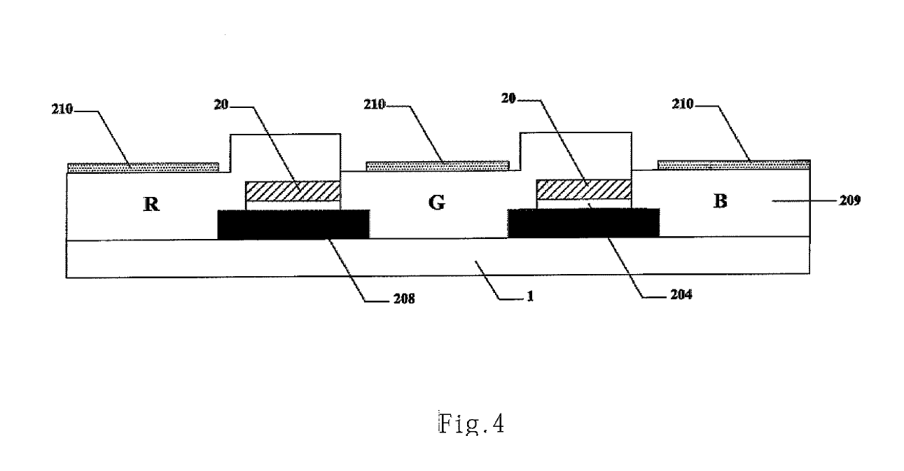

With reference to both FIG. 2 and FIG. 4, for the purpose of preventing light leakage, a width of the black matrix 208 in an extension direction of the gate line 10 is preferably larger than a width of the gate line 10, and the width of the black matrix 208 in an extension direction of the data line 20 which is disposed above the matrix 208 is preferably larger than a width of the data line 20.

Alternatively, with reference to FIG. 2, an orthographic projection of the black matrix 208 on the substrate 1 and that of the pixel electrode 210 on the substrate 1 partially overlap, in the extension direction of the gate line 10. The red, green and blue regions of the color filter layer 209 having three respective primary colors are sequentially disposed in three adjacent sub-pixel regions, while overlaying the data line on the right side, so as to provide insulation protection for the source electrode 205 and the drain electrode 206.

An embodiment of the invention further provides a display comprising the above TFT array substrate. The quality of the display is further improved as the above modified TFT array substrate is used.

The method for fabricating a TFT array substrate comprising the steps of

Step 100: forming a gate electrode on a substrate;

Step 200: forming a black matrix on the gate electrode;

Step 300: sequentially forming an active layer and a source/drain electrode on the black matrix;

Step 400: forming a color filter layer on both the active layer and the source/drain electrode, the color filter layer has a via hole at a location corresponding to the drain electrode;

Step 500: forming a pixel electrode on the color filter layer, the pixel electrode is connected to the drain electrode by way of the via hole in the color filter layer.

In the above method, a mask process is needed for steps 100, 200, 300 and 500 respectively. When the color filter layer is one having three primary colors, step 400 requires three mask processes. Therefore, the whole fabrication method totally requires seven mask processes, which significantly simplifies the method for fabricating the substrate, in comparison with the conventional eight-mask-process method. Meanwhile, two plasma vapor film formation processes are saved, which significantly shortens the process time, reduces the process complexity, the production cost and the thickness of the substrate.

As an example, the step 100 may comprise:

Step 11: providing a substrate;

Step 12: depositing a gate metal film on the substrate;

Step 13: coating a photoresist layer on the gate metal film;

Step 14: exposing the photoresist by using a mask to form a photoresist-removed region and a photoresist-retained region, the photoresist-retained region corresponds to a region having the pattern of the gate line and the gate electrode, the photoresist-removed region corresponds to the region other than the above pattern;

Step 15: developing the substrate to have the photoresist in the photoresist-removed region completely removed and the photoresist in the photoresist-retained region retained and its thickness remained the same;

Step 16: completely etching the gate metal film in the photoresist-removed region through an etching process to form the pattern of the gate line and the gate electrode;

Step 17: peeling the remaining photoresist off.

As an example, the step 200 may comprise:

Step 21: forming a photosensitive black resin material on the substrate having the gate electrode formed thereon;

Step 22: exposing and developing the photosensitive black resin material by using a mask to obtain the pattern of the black matrix.

As an example, the step 300 may comprise:

sequentially depositing an active layer and a source/drain metal layer on the substrate having the black matrix formed thereon, exposing and then etching for several times to obtain the patterns of the source/drain electrode and the active layer.

As an example, the step 400 comprises:

Step 41: forming a color filter resin layer on the substrate having the active layer and the source/drain electrode formed thereon;

Step 42: exposing and developing the color filter resin layer by using a mask to obtain the pattern of the color filter layer having the via hole which expose the drain electrode.

As an example, the step 500 comprises:

depositing a pixel electrode layer on the substrate having the color filter layer formed thereon, forming the pattern of the pixel electrode through a mask process such that the pixel electrode is connected with the drain electrode by way of the via hole in the color filter layer.

What are described above is related to the illustrative embodiments of the disclosure only and not limitative to the scope of the disclosure; the scopes of the disclosure are defined by the accompanying claims.

1. A Thin Film Transistor (TFT) array substrate, comprising a plurality of gate lines, a plurality of data lines and a plurality of pixel regions defined by intersecting the plurality of gate lines and the plurality of data lines, a pixel electrode is disposed in each of the pixel regions, the TFT array substrate further comprises:
a gate electrode formed on a substrate;
a black matrix and an active layer sequentially formed above the gate electrode, the gate electrode and the active layer are isolated from each other via the black matrix overlaying the gate electrode;
a source electrode and a drain electrode both formed on the active layer;
a color filter layer formed on the source electrode, the drain electrode and the active layer; the pixel electrode is disposed on the color filter layer and connected to the drain electrode by way of a via hole penetrating through the color filter layer.

2. The TFT array substrate of claim 1, wherein a permittivity of a material of the black matrix is 4 to 5.

3. The TFT array substrate of claim 1, wherein a material of the black matrix is photosensitive black resin with metal powder uniformly dispersed therein.

4. The TFT array substrate of claim 3, wherein the metal powder is silver powder or copper powder or a mixture of them.

5. The TFT array substrate of claim 1, wherein a width of the black matrix in an extension direction of the gate line is larger than a width of the gate line, and a width of the black matrix in an extension direction of the data line is larger than a width of the data line.

6. The TFT array substrate of claim 1, wherein in the extension direction of the gate line, an orthographic projection of the black matrix on the substrate and that of the pixel electrode on the substrate partially overlap.

7. A display device comprising the TFT array substrate of claim 1.

8. A method for fabricating a TFT array substrate, comprising:
forming a gate electrode on a substrate;
forming a black matrix on the gate electrode;
sequentially forming an active layer, a source electrode and drain electrode on the black matrix;
forming a color filter layer on the active layer, the source electrode and the drain electrode, the color filter layer has a via hole at a location corresponding to the drain electrode;
forming a pixel electrode on the color filter layer, the pixel electrode is connected to the drain electrode by way of the via hole in the color filter layer.

9. The method of claim 8, wherein a permittivity of a material of the black matrix is 4 to 5.

10. The method of claim 8, wherein a material of the black matrix is photosensitive black resin with metal powder uniformly dispersed therein.

11. The method of claim 10, wherein the metal powder is silver powder or copper powder or a mixture of them.

12. The display device of claim 7, wherein a permittivity of a material of the black matrix is 4 to 5.

13. The display device of claim 7, wherein a material of the black matrix is photosensitive black resin with metal powder uniformly dispersed therein.

14. The display device of claim 13, wherein the metal powder is silver powder or copper powder or a mixture of them.

15. The display device of claim 7, wherein a width of the black matrix in an extension direction of the gate line is larger than a width of the gate line, and a width of the black matrix in an extension direction of the data line is larger than a width of the data line.

16. The display device of claim 7, wherein in the extension direction of the gate line, an orthographic projection of the black matrix on the substrate and that of the pixel electrode on the substrate partially overlap.
